(19) United States
(12) Patent Application Publication
(10) Pub. No.: US 2026/0344403 A1
(43) Pub. Date: Oct. 29, 2026

(54) METHOD OF FORMING SEMICONDUCTOR PACKAGE AND STRUCTURE THEREOF

(71) Applicant: TAIWAN SEMICONDUCTOR MANUFACTURING COMPANY, LTD., Hsinchu (TW)

(72) Inventors: Wei Hsiang CHAN, Hsinchu (TW); Chih-Pin CHIU, Hsinchu (TW); Chi-Feng LIN, Hsinchu (TW); Liang-Wei WANG, Hsinchu (TW)

(73) Assignee: TAIWAN SEMICONDUCTOR MANUFACTURING COMPANY, LTD., Hsinchu (TW)

(21) Appl. No.: 19/188,675

(22) Filed: Apr. 24, 2025

(51) Int. Cl. H10W 20/41; H10W 20/00; H10W 20/20; H10W 20/43; H10W 80/00; H10W 90/00; H10W 90/20

(52) U.S. Cl. CPC H10W 20/427; H10W 20/069; H10W 20/20; H10W 20/43; H10W 90/00; H10W 80/312; H10W 80/327; H10W 90/20; H10W 90/792

(57) ABSTRACT

A semiconductor package includes a first semiconductor die having a first power rail feature on top side thereof, a second semiconductor die having a second power rail feature on bottom side thereof, a first bonding film disposed on bottom side of the first semiconductor die, a second bonding film disposed on top side of the second semiconductor die, wherein the first semiconductor die and the second semiconductor die are bonded to each other through the first bonding film and the second bonding film, and a though-substrate-via formed in the second semiconductor die from the bottom side thereof, wherein the though-substrate-via passes through the first bonding film and the second bonding film for electrically connecting to the first semiconductor die.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed and greater bandwidth, as well as lower power consumption and latency has grown recently, there has grown a need for smaller and more creative packaging techniques of semiconductor dies. Currently, semiconductor packages (e.g., System-on-Integrated-Chips (SoIC)) are becoming increasingly popular for their multi-functions and compactness. However, there are challenges related to such semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart schematically illustrating a method of forming a semiconductor package in accordance with some embodiments of the present disclosure.

FIG. 2A to FIG. 8A are cross-sectional views schematically illustrating a method of forming a semiconductor package in accordance with some embodiments of the present disclosure.

FIG. 8B is an enlarged view schematically illustrating a through-substrate-via in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Stacking dies featuring ultra-high-density-vertical stacking (often using hybrid bonding) is sometimes referred to System on Integrated Chips (SoIC) technologies. SoIC technologies can achieve high performance, low power, and minimum resistance-inductance-capacitance (RLC). SoIC technologies integrate active and passive chips that are partitioned from System on Chip (SoC), into a new integrated SoC system, which is electrically identical to native SoC, to achieve better form factor and performance. A die stack bonded together using hybrid bonding is sometimes, therefore, referred to as a SoIC die stack (“SoIC die stack” and “die stack” are used interchangeably throughout the disclosure).

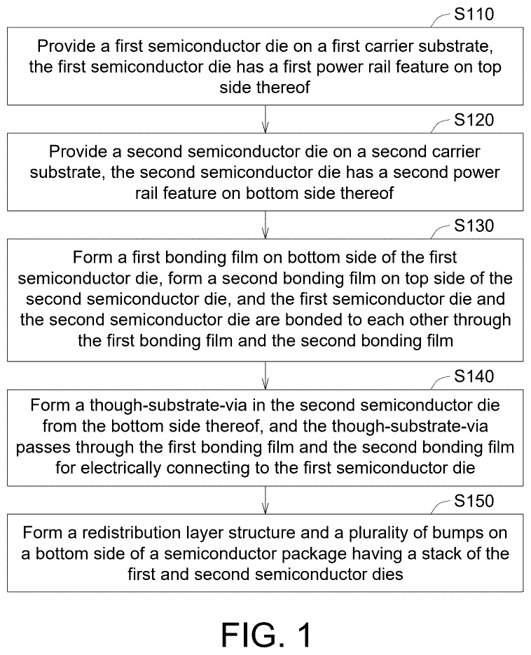

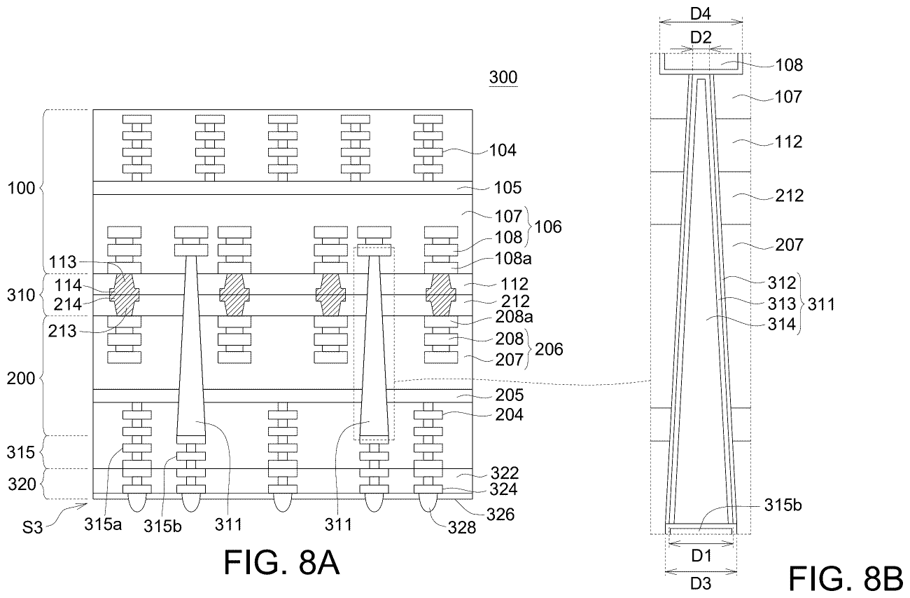

FIG. 1 is a flow chart schematically illustrating a method of forming a semiconductor package in accordance with some embodiments of the present disclosure. The final structure of the semiconductor package 300 is disclosed in FIG. 8A. The method of forming the semiconductor package 300 includes the following steps S110-S150. In step S110, a first semiconductor die 100 is provided on a first carrier substrate 102. The first semiconductor die 100 has a first power rail feature 104 on top side thereof. In step S120, a second semiconductor die 200 is provided on a second carrier substrate 202. The second semiconductor die 200 has a second power rail feature 204 on bottom side thereof. In step S130, a first bonding film 112 is formed on bottom side of the first semiconductor die 100, a second bonding film 212 is formed on top side of the second semiconductor die 200, and the first semiconductor die 100 and the second semiconductor die 200 are bonded to each other through the first bonding film 112 and the second bonding film 212. In step S140, a though-substrate-via 311 is formed in the second semiconductor die 200 from the bottom side thereof, and the though-substrate-via 311 passes through the first bonding film 112 and the second bonding film 212 for electrically connecting to the first semiconductor die 100. In step S150, a redistribution layer structure 320 and a plurality of bumps 328 are formed on a bottom side (i.e. bottom side S3) of a semiconductor package 300 having a stack of the first and second semiconductor dies 100 and 200.

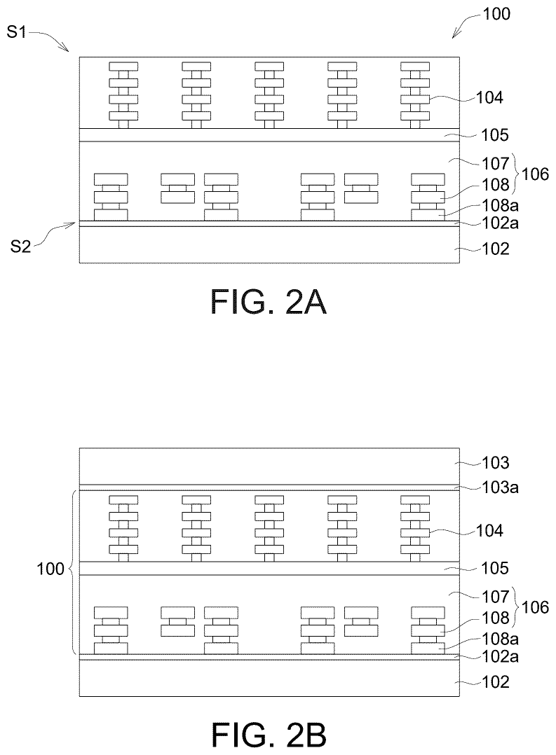

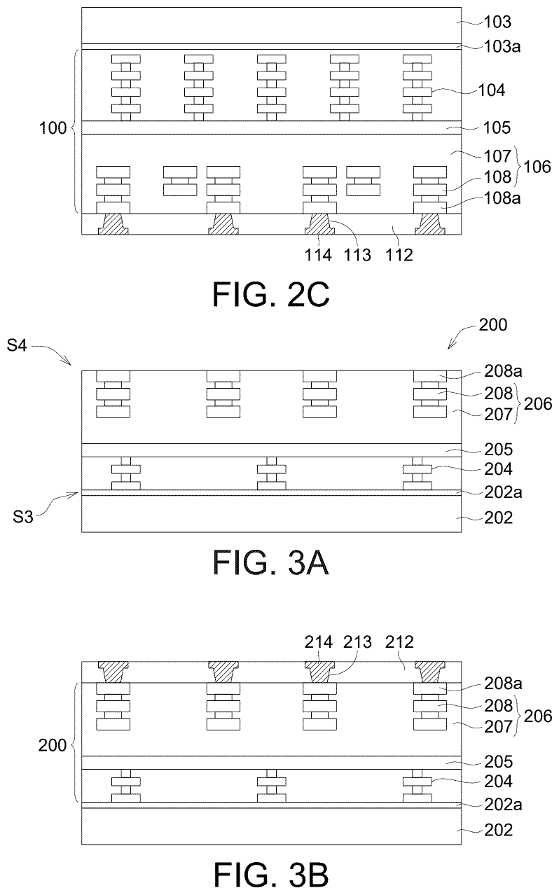

FIGS. 2A-2C, 3A-3B, 4, 5, 6, 7A-7B and 8A are cross-sectional views schematically illustrating a method of forming a semiconductor package in accordance with some embodiments of the present disclosure. It is understood that the disclosure is not limited by the method described below. Additional operations can be provided before, during, and/or after the method and some of the operations described below can be replaced or eliminated, for additional embodiments of the methods. Although FIGS. 2A-2C, 3A-3B, 4, 5, 6, 7A-7B and 8A are described in relation to a method according to FIG. 1, it is appreciated that the structures disclosed in FIGS. 2A-2C, 3A-3B, 4, 5, 6, 7A-7B and 8A are not limited to such a method, but instead may stand alone as structures independent of the method.

Referring to FIG. 2A, a first semiconductor die 100 (e.g., logic dies, memory dies, or the like) is provided on a first carrier substrate 102. In FIG. 2A, only one first semiconductor die 100 is illustrated; however, the number of the first semiconductor die 100 is not limited by the disclosure. In some embodiments, the first semiconductor die 100 includes a top side S1 (e.g., front surface) and a bottom side S2 (e.g., back surface) opposite to the top side S1. In some embodiments, the first semiconductor die 100 includes a first power rail feature 104, a first interconnect structure 106 and at least one first device layer 105 disposed between the first power rail feature 104 and the first interconnect structure 106. Throughout the description, the side of the first semiconductor die 100 having the first interconnect structure 106 is referred to as the bottom side S2, and the side of the first semiconductor die 100 having the first power rail feature 104 is referred to as the top side S1.

The first carrier substrate 102 may be a semiconductor wafer, such as a silicon wafer, and the bonding film 102a may be a bonding layer prepared for fusion bond. The semiconductor wafer include an elementary semiconductor such as silicon, germanium and/or a compound semiconductor such as silicon germanium, silicon carbide, gallium arsenic, indium arsenide, gallium nitride or indium phosphide. In some embodiments, the bonding film 102a is a deposited layer formed over the top surface of the carrier substrate 102. In other embodiments, the bonding film 102a is a portion of the carrier substrate 102 for fusion bond. In some embodiments, the bonding film 102a includes silicon (Si), silicon oxide (SiOx, where x>0), silicon nitride (SiNx, where x>0), silicon oxynitride (SiOxNy, where x>0 and y>0) or other suitable bonding materials.

The first power rail feature 104 may be connected to a source/drain region of the first device layer 105 through vias or contacts. The first power rail feature 104 may be front-side power rails, which are conductive lines that electrically connect the epitaxial source/drain regions and/or the gate electrode of the first device layer 105 to a reference voltage, a supply voltage, or the like. In addition, the first power rail feature 104 and the first interconnect structure 106 may be connected through vias or contacts.

The first device layer 105 is disposed over the first interconnect structure 106 and includes one or more functional devices. The functional devices may include active components, passive components, or a combination thereof. In some embodiments, the functional devices may include integrated circuits devices. The functional devices are, for example, transistors, capacitors, resistors, diodes, photodiodes, fuse devices and/or other similar devices. In some embodiments, the first semiconductor die 100 may be referred to as a “first device die,” “first-tier semiconductor die,” or “first integrated circuit structure”.

The first interconnect structure 106 is disposed on the first carrier substrate 102 and electrically connected to the first device layer 105. The first interconnect structure 106 may include one or more dielectric layers, collectively referred to as the first dielectric layer 107, and first metal features 108 embedded in the at least one first dielectric layer 107. The first metal features 108 are disposed in the first dielectric layer 107 and electrically connected with each other.

In some embodiments, the first dielectric layer 107 includes an inter-layer dielectric (ILD) layer and at least one inter-metal dielectric (IM D) layer over the inter-layer dielectric layer. In some embodiments, the first dielectric layer 107 includes silicon oxide, silicon oxynitride, silicon nitride, a low dielectric constant (low-k) material or a combination thereof. The first dielectric layer 107 may be a single layer or a multiple-layer structure. In some embodiments, the first metal features 108 include metal plugs and metal lines. The metal plugs may include contacts formed in the inter-layer dielectric layer, and vias formed in the inter-metal dielectric layer. The contacts are formed between and in contact with a top metal line and the first device layer 105. The vias are formed between and in contact with two metal lines. The first metal features 108 may include Cu, Ti, Ta, W, Ru, Co, Ni, the like, an alloy thereof, or a combination thereof. In some embodiments, a barrier layer may be disposed between each first metal feature 108 and the first dielectric layer 107 to prevent the material of the first metal feature 108 from migrating to the first device layer 105. The barrier layer includes Ta, TaN, Ti, TiN, CoW, the like, or a combination thereof, for example.

In some embodiments, the first interconnect structure 106 is formed by a dual damascene process. In other embodiments, the first interconnect structure 106 is formed by multiple single damascene processes. In other embodiments, the first interconnect structure 106 is formed by an electroplating process.

In FIG. 2B, a transfer carrier substrate 103 is formed on the top side S1 of the first semiconductor die 100 to support the first semiconductor die 100 first, and then the first carrier substrate 102 on the bottom side S2 of the first semiconductor die 100 is removed by a chemical-mechanical polishing (CM P) process. After the CM P process, the bottommost metal features 108a of the first metal features 108 are exposed by the first dielectric layer 110.

Next, referring to FIG. 2C, a first bonding film 112 is formed on the bottom side S2 of the first semiconductor die 100. The first bonding film 112 may include multiple sub-layers each formed of an oxide, a nitride, or a combination thereof, such as un-doped silicate glass (USG) or high density plasma (HDP) chemical vapor deposition oxide. Planarization processes, such as a CM P process, may be performed to planarize the deposited first bonding film 112. Next, first bonding pads 114 are formed in the first bonding film 112. Each of the first bonding pads 114 includes a bonding pad via (BPV) 113. The formation of one of the first bonding pads 114 includes etching the first bonding film 112 to form a trench and a via opening at first and subsequently filling an electrically conductive material (e.g., copper, tungsten, other metals, metal alloy, or the like) in the trench and the via opening as the bonding pad metal and the BPV 113, respectively. The conductive materials in the first bonding pads 114 and the subsequently formed redistribution layer (RDL) may be the same or different, depending on device performance and/or cost requirements.

In FIG. 2C, the first bonding pads 114 are electrically connected to the first interconnect structure 106. In some embodiments, each of the first bonding pads 114 is in physical contact with a corresponding one of the bottommost metal features 108a of the first metal features 108 through one of the BPVs 113.

Referring to FIG. 2C, the transfer carrier substrate 103 includes a bonding film 103a disposed thereon. The transfer carrier substrate 103 may be a semiconductor wafer such as a silicon wafer, and the bonding film 103a may be a bonding layer prepared for fusion bond. In some embodiments, the bonding film 103a is a deposited layer formed over the top surface of the transfer carrier substrate 103. In other embodiments, the bonding film 103a is a portion of the transfer carrier substrate 103 for fusion bond. In some embodiments, the bonding film 103a includes silicon (Si), silicon oxide (SiOx, where x>0), silicon nitride (SiNx, where x>0), silicon oxynitride (SiOxNy, where x>0 and y>0) or other suitable bonding materials.

Referring to FIG. 3A, a second semiconductor die 200 (e.g., logic dies, memory dies, or the like) is provided on a second carrier substrate 202. In FIG. 3A, only one second semiconductor die 200 is illustrated; however, the number of the second semiconductor die 200 is not limited by the disclosure. In some embodiments, the second semiconductor die 200 includes a top side S4 (e.g., front surface) and a bottom side S3 (e.g., back surface) opposite to the top side S4. In some embodiments, the second semiconductor die 200 includes a second power rail feature 204, a second interconnect structure 206, and at least one second device layer 205 disposed between the second power rail feature 204 and the second interconnect structure 206. Throughout the description, the side of the second semiconductor die 200 having the second interconnect structure 206 is referred to as the top side S4, and the side of the second semiconductor die 200 having the second power rail feature 204 is referred to as the bottom side S3.

The second carrier substrate 202 may be a semiconductor wafer, such as a silicon wafer, and the bonding film 202a may be a bonding layer prepared for fusion bond. The semiconductor wafer include an elementary semiconductor such as silicon, germanium and/or a compound semiconductor such as silicon germanium, silicon carbide, gallium arsenic, indium arsenide, gallium nitride or indium phosphide. In some embodiments, the bonding film 202a is a deposited layer formed over the top surface of the second carrier substrate 202. In other embodiments, the bonding film 202a is a portion of the second carrier substrate 202 for fusion bond. In some embodiments, the bonding film 202a includes silicon (Si), silicon oxide (SiOx, where x>0), silicon nitride (SiNx, where x>0), silicon oxynitride (SiOxNy, where x>0 and y>0) or other suitable bonding materials.

The second power rail feature 204 may be connected to a source/drain region of the second device layer 205 through vias or contacts. The second power rail feature 104 may be back-side power rails, which are conductive lines that electrically connect the epitaxial source/drain regions and/or the gate electrode of the second device layer 205 to a reference voltage, a supply voltage, or the like. In addition, the second power rail feature 204 and the second interconnect structure 206 may be connected through vias or contacts.

The second device layer 205 is disposed over the second interconnect structure 206 and includes one or more functional devices. The functional devices may include active components, passive components, or a combination thereof. In some embodiments, the functional devices may include integrated circuits devices. The functional devices are, for example, transistors, capacitors, resistors, diodes, photodiodes, fuse devices and/or other similar devices. In some embodiments, the second semiconductor die 200 may be referred to as a “second device die,” “second-tier semiconductor die,” or “second integrated circuit structure”.

The second interconnect structure 206 is disposed on the second device layer 205 and electrically connected to the second device layer 205. The second interconnect structure 206 may include one or more dielectric layers, collectively referred to as the second dielectric layer 207, and second metal features 208 embedded in the at least one second dielectric layer 207. The second metal features 208 are disposed in the second dielectric layer 207 and electrically connected with each other.

In some embodiments, the second dielectric layer 207 includes an inter-layer dielectric (ILD) layer and at least one inter-metal dielectric (IMD) layer over the inter-layer dielectric layer. In some embodiments, the second dielectric layer 207 includes silicon oxide, silicon oxynitride, silicon nitride, a low dielectric constant (low-k) material or a combination thereof. The second dielectric layer 207 may be a single layer or a multiple-layer structure. In some embodiments, the second metal features 208 include metal plugs and metal lines. The metal plugs may include contacts formed in the inter-layer dielectric layer, and vias formed in the inter-metal dielectric layer. The contacts are formed between and in contact with a bottom metal line and the second device layer 205. The vias are formed between and in contact with two metal lines. The second metal features 208 may include Cu, Ti, Ta, W, Ru, Co, Ni, the like, an alloy thereof, or a combination thereof. In some embodiments, a barrier layer may be disposed between each second metal feature 208 and the second dielectric layer 207 to prevent the material of the second metal feature 208 from migrating to the second device layer 205. The barrier layer includes Ta, TaN, Ti, TiN, CoW, the like, or a combination thereof, for example.

In some embodiments, the second interconnect structure 206 is formed by a dual damascene process. In other embodiments, the second interconnect structure 206 is formed by multiple single damascene processes. In other embodiments, the second interconnect structure 206 is formed by an electroplating process.

In FIG. 3A, the topmost metal features 208a of the second metal features 208 are exposed by the second dielectric layer 207.

Next, referring to FIG. 3B, a second bonding film 212 is formed on the top side S4 of the second semiconductor die 200. The second bonding film 212 may include multiple sub-layers each formed of an oxide, a nitride, or a combination thereof, such as un-doped silicate glass (USG) or high density plasma (HDP) chemical vapor deposition oxide. Planarization processes, such as a CM P process, may be performed to planarize the deposited second bonding film 212. Next, second bonding pads 214 are formed in the second bonding film 212. Each of the second bonding pads 214 includes a bonding pad via (BPV) 213. The formation of one of the second bonding pads 214 includes etching the second bonding film 212 to form a trench and a via opening at first and subsequently filling an electrically conductive material (e.g., copper, tungsten, other metals, metal alloy, or the like) in the trench and the via opening as the bonding pad metal and the BPV 213, respectively. The conductive materials in the second bonding pads 214 and the subsequently formed redistribution layer (RDL) may be the same or different, depending on device performance and/or cost requirements.

In FIG. 3B, the second bonding pads 214 are electrically connected to the second interconnect structure 206. In some embodiments, each of the second bonding pads 214 is in physical contact with a corresponding one of the topmost metal features 208a of the second metal features 208 through one of the BPV s 213.

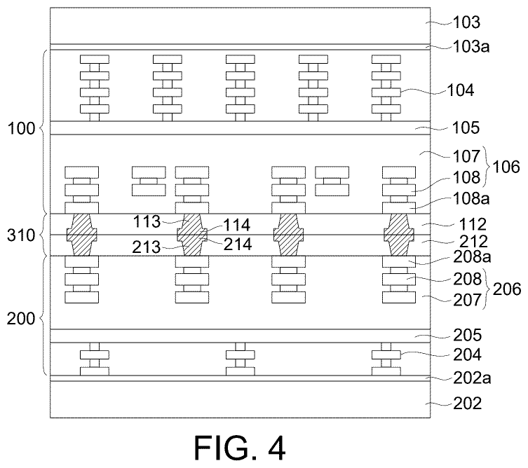

Referring to FIG. 4, the first semiconductor die 100 and the second semiconductor die 200 are electrically connected by hybrid bonding process. For example, the first bonding pads 114 at the bottom side S2 of the first semiconductor die 100 are electrically connected to the second bonding pads 124 at the top side S4 of the second semiconductor die 200, respectively. Therefore, in FIG. 4, a bonding structure 310 is formed between the first semiconductor die 100 and the second semiconductor die 200. The bonding structure 310 is referred to a “blanket bonding structure” in some examples, because the bonding structure 310 is formed across the first and second semiconductor dies 100 and 200 and extends between the first and second semiconductor dies 100 and 200. That is, the first semiconductor die 100 and the second semiconductor die 200 are electrically connected through the bonding structure 310. The first semiconductor die 100, the second semiconductor die 200 and the bonding structure 300 are stacked to each other to form a semiconductor package with stacked dies.

In some embodiments, some of the first and second bonding pads are referred to “dummy bonding pads” or “floating bonding pads” in some examples because they are provided to merely enhance the bonding strength between the first and second semiconductor dies. In some embodiments, the sizes (e.g., widths) of the bonding pads are the same, as shown in FIG. 4. However, the disclosure is not limited thereto. In other embodiments, the first and second bonding pads can have the same size.

In some embodiments, the first bonding pads 114 are aligned with the second bonding pads 214, a wafer-to-wafer hybrid bonding or die-to-wafer hybrid bonding is performed such that the second semiconductor die 200 is hybrid bonded to the first semiconductor die 100. In some embodiments, the first semiconductor die 100 and the second semiconductor die 200 may be bonded through a face-to-back hybrid bonding process. However, the disclosure is not limited thereto. In some embodiments, the first semiconductor die 100 and the second semiconductor die 200 may be bonded through a face-to-face hybrid bonding process.

The hybrid bonding of the first semiconductor die 100 and the second semiconductor die 200 may include a treatment for dielectric bonding and a thermal annealing for conductor bonding. The treatment for dielectric bonding is performed to strengthen the bonding between the first bonding film 112 and the second bonding film 212. The treatment for dielectric bonding may be performed at temperature ranging from about 100 Celsius degree to about 150 Celsius degree, for example. After performing the treatment for dielectric bonding, the thermal annealing for conductor bonding is performed to facilitate the bonding between the first bonding pads 114 and the second bonding pads 214. The thermal annealing for conductor bonding may be performed at temperature ranging from about 300 Celsius degree to about 400 Celsius degree, for example. The process temperature of the thermal annealing for conductor bonding is higher than that of the treatment for dielectric bonding. Since the thermal annealing for conductor bonding is performed at relative higher temperature, metal diffusion and grain growth may occur at bonding interfaces between the first bonding pads 114 and the second bonding pads 214. The conductor bonding is not limited to the pad-to-pad bonding. via-to-via bonding or via-to-pad bonding may be applied as needed.

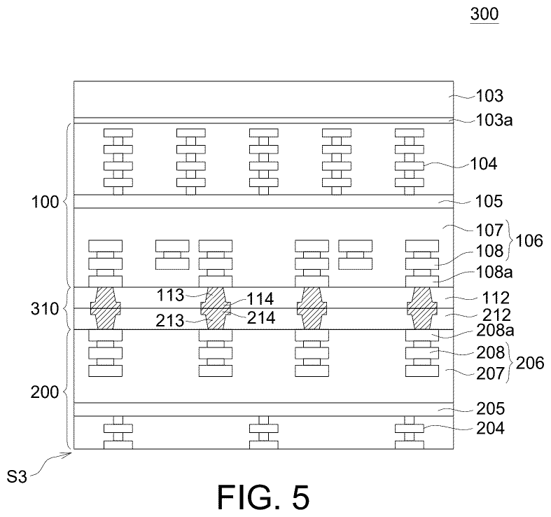

Referring to FIG. 5, after the first semiconductor dies 100 are bonded to the second semiconductor die 200 through the bonding structure 310, the second carrier substrate 202 is removed by CM P process to expose the bottom side of the semiconductor die 200.

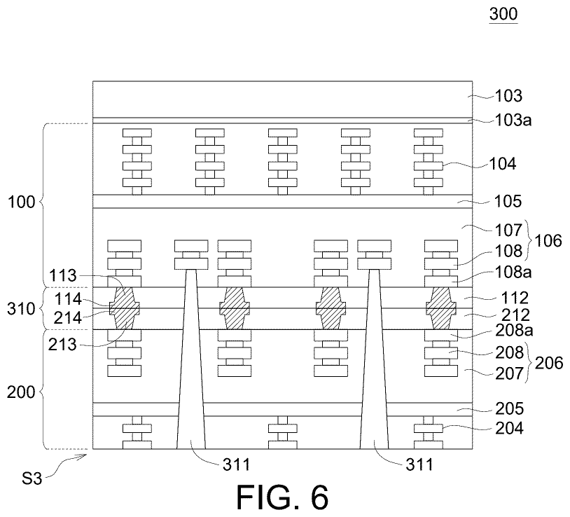

Referring to FIG. 6, through-substrate-vias (TSVs) 311 are formed in the semiconductor package 300 and electrically connected to the first interconnect structure 106 of the first semiconductor die 100 for transmitting power signals to the first device layer 105. As illustrated in FIG. 6, the through-substrate-vias 311 are embedded in the second semiconductor die 200 and the bonding structure 310, and one end (i.e., lower end) of the through-substrate-vias 311 is revealed from the bottom side of the second semiconductor die 200 at this stage, and the other end (i.e., upper end) of the through-substrate-vias 311 is electrically connected to the first interconnect structure 106 of the first semiconductor die 100. The through-substrate-vias 311 may include Cu, Ti, Ta, W, Ru, Co, Ni, the like, an alloy thereof, or a combination thereof. In some embodiments, the through-substrate-vias 311 are formed by an electroplating process and may comprise one or more layers, such as barrier layers, adhesion layers, fill material, and/or the like.

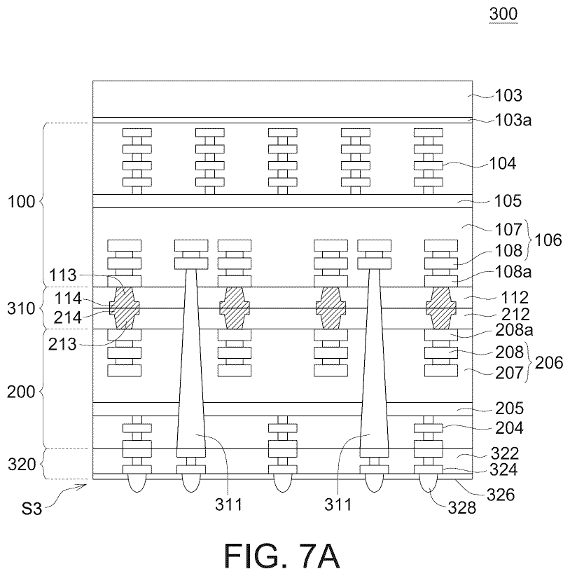

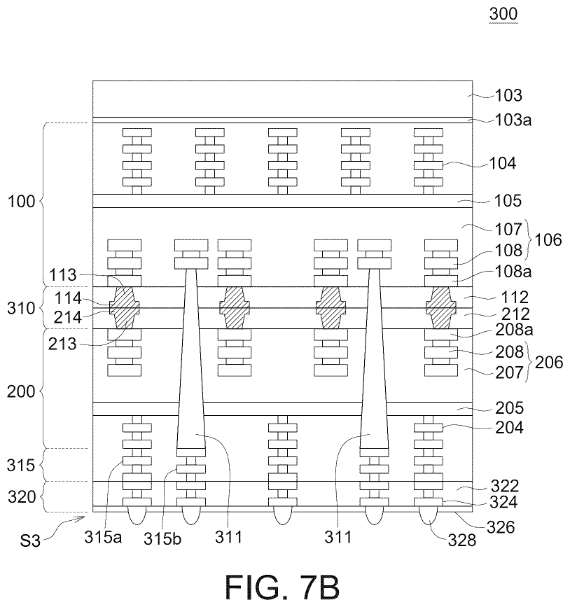

Referring to FIG. 7A, in some embodiments, a redistribution layer structure 320 is formed over the bottom sides S2 of the second semiconductor dies 200. The redistribution layer structure 320 includes at least one polymer layer 322 and conductive features 324 embedded in the polymer layer 322. The conductive features 324 include metal pads, metal lines and/or metal vias configured to electrically connect to different components. In some embodiments, the polymer layer 322 includes a photo-sensitive material such as polybenzoxazole (PBO), polyimide (PI), benzocyclobutene (BCB), a combination thereof or the like. The polymer layer 322 of the redistribution layer structure 320 may be replaced by a dielectric layer or an insulating layer as needed. In some embodiments, the conductive features 324 include Cu, Ti, Ta, W, Ru, Co, Ni, the like, an alloy thereof, a combination thereof, or the like. In some embodiments, a seed layer and/or a barrier layer may be disposed between each conductive feature 324 and the polymer layer 322. The seed layer may include Ti/Cu. The barrier layer may include Ta, TaN, Ti, TiN, CoW, a combination thereof, or the like.

Still referring to FIG. 7A, a patterning process of a passivation layer 326 of the redistribution layer structure 320 is performed, such that multiple openings are formed in the passivation layer 326 and expose the conductive features 324. In some embodiments, photolithography and etching processes are performed to form the openings. However, the disclosure is not limited thereto. In other embodiments, a laser drilling process is performed to form the openings.

Thereafter, conductive terminals or bumps 328 are formed within the openings of the passivation layer 326 and electrically connected to the conductive features 324 of the semiconductor package 300. In some embodiments, the bumps 328 include solder bumps, and/or may include metal pillars (e.g., copper pillars), solder caps formed on metal pillars, and/or the like. The bumps 328 may be formed by a suitable process such as evaporation, electroplating, ball drop, or screen printing.

Referring to FIG. 7B, in some embodiments, before the redistribution layer structure 320 is formed over the bottom sides S3 of the second semiconductor dies 200, additional or post power rail features 315 may be formed on the bottom side S3 of the second semiconductor dies 200. The post power rail features 315 are used to expand the size or the number of contact/via chains of the second power rail feature 204. In some embodiments, at least one feature 315a of the post power rail features 315 is in contact with and electrically connected to the second power rail features 204, and at least one feature 315b of the post power rail features 315 is in contact with and electrically connected to the through-substrate-vias 311. The size (or width) of the contact pads of the post power rail features 315 may be greater than the size (or width) of the through-substrate-vias 311 and the size (or width) of the contact pads of the second power rail features 204.

Still referring to FIG. 7B, after forming the redistribution layer structure 320 on the post power rail features 315, a patterning process of a passivation layer 326 of the redistribution layer structure 320 is performed, such that multiple openings are formed in the passivation layer 326 and expose the conductive features 324. In some embodiments, photolithography and etching processes are performed to form the openings. However, the disclosure is not limited thereto. In other embodiments, a laser drilling process is performed to form the openings.

Referring to FIG. 8A, after forming the bumps 328 on the bottom side S3 of the semiconductor package 300, the transfer carrier substrate 103 may be removed by a chemical-mechanical polishing (CM P) process.

Referring to FIGS. 8A and 8B, FIG. 8B is an enlarged view schematically illustrating a through-substrate-via 311 of FIG. 8A in accordance with some embodiments of the present disclosure. In FIG. 8A, the first and second semiconductor dies 100 and 200 are stacked such that the first interconnect structure 106 of the first semiconductor die 100 at bottom side thereof is electrically connected to the second interconnect structure 206 of the second semiconductor die 200 at top side thereof. In addition, the first power rail feature 104 of the first semiconductor die 100 at top side thereof is electrically connected to the second power rail feature 204 of the second semiconductor die 200 at bottom side thereof through the through-substrate-via 311. That is, the through-substrate-via 311 is a power delivery TSV structure, which has a dimension (i.e., diameter) greater than or equal to the dimension of micro-TSV structure. In some embodiments, the through-substrate-via 311 has a first dimension D1 and a second dimension D2 on opposite ends thereof. The first dimension D1 is in a range between about 1 μm and 3 μm, and the second dimension D2 is in a range between about 1 μm and 3 μm. The post power rail feature 315a connected to the one end of the through-substrate-via 311 has a third dimension D3 in a range between about 0.2 μm and 3.5 μm, depending on the first dimension D1 of the through-substrate-via 311. The first metal feature 108 connected to the one end of the through-substrate-via 311 has a fourth dimension D4 in a range between about 1 μm and 4 μm, depending on the second dimension D2 of the through-substrate-via 311. The vertical length of the through-substrate-via 311 may be in a range between about 10 μm and 50 μm.

In some embodiments, the first dimension D1 may in a range between about 3 μm and 6 μm, and the second dimension D2 is in a range between about 3 μm and 6 μm. The fourth dimension D4 may be in a range between about 3 μm and 7 μm, and the third dimension D3 may be in a range between about 0.2 μm and 6.5 μm. The vertical length of the through-substrate-via 311 may be in a range between about 10 μm and 50 μm.

As used herein, “through-substrate-via-power-connection” refers to a connection method or a connection structure in which an array of through-substrate via (TSV) structures, vertically extending through at least one bonding film (112 and/or 212), is used to provide electrical connection between the first semiconductor die 100 and the second semiconductor die 200. The first power rail feature 104, the second power rail feature 204, the post power rail feature 315 and the through-substrate via 311 may be integrated as a power rail system. In some embodiments, as shown in the configuration of FIG. 8A, the through-substrate-via 311 is used to deliver the power signal and/or control signal from the bottom side S3 of the semiconductor package 300 to the top side thereof directly such that the semiconductor package 300 designs with an emphasis on reducing interconnect lengths to reduce ohmic loss, heat generation, and signal delay.

As shown in FIG. 8B, the through-substrate-via 311 includes a liner 312, a barrier layer 313 and a fill material 314. The barrier layer 313 may be disposed between the liner 312 and the fill material 314 to prevent the fill material 314 from migrating to the first dielectric layer and the second dielectric layer. The barrier layer 313 includes Ta, TaN, Ti, TiN, CoW, the like, or a combination thereof, for example. The liner 312 may be disposed around the barrier layer 313 and the fill material 314 to prevent the water vapor/moisture from penetrating the through-substrate-via 311. The liner 312 includes silicon nitride (SINx), silicon oxynitride (SiOxNy) or other suitable insulating materials. The fill material 314 may include Cu, Ti, Ta, W, Ru, Co, Ni, the like, an alloy thereof, or a combination thereof. In some embodiments, the through-substrate-via 311 may include the barrier layer 313 and the fill material 314 without the liner 312.

The present disclosure is related to a method of forming a semiconductor package with stacked semiconductor dies. In some embodiments, the first interconnect structure of the first semiconductor die is hybrid bonded to the second interconnect structure of the second semiconductor die for electrically connecting the first device layer and the second device layer. The first and second semiconductor dies include frontside/backside power rail features which allows for the semiconductor dies to be formed with greater transistor densities, reduces distances between bonded semiconductor dies, and provides for greater flexibility in semiconductor die stacking and packaging. The semiconductor package include die-to-die through-substrate-via (TSV) which provide power signal transmission and is compatible with super power rail process.

According to some embodiments of the present disclosure, a method of forming a semiconductor package is provided. A first semiconductor die is provided on a first carrier substrate. The first semiconductor die has a first power rail feature on top side thereof. A second semiconductor die is provided on a second carrier substrate. The second semiconductor die has a second power rail feature on bottom side thereof. A first bonding film is formed on bottom side of the first semiconductor die, a second bonding film is formed on top side of the second semiconductor die, and the first semiconductor die and the second semiconductor die are bonded to each other through the first bonding film and the second bonding film. A though-substrate-via is formed in the second semiconductor die from the bottom side thereof, and the though-substrate-via passes through the first bonding film and the second bonding film for electrically connecting to the first semiconductor die. A redistribution layer structure and a plurality of bumps are formed on a bottom side of a semiconductor package having a stack of the first and second semiconductor dies.

According to some embodiments of the present disclosure, a semiconductor package includes a first semiconductor die having a first power rail feature on top side thereof, a second semiconductor die having a second power rail feature on bottom side thereof, a first bonding film disposed on bottom side of the first semiconductor die, a second bonding film disposed on top side of the second semiconductor die, wherein the first semiconductor die and the second semiconductor die are bonded to each other through the first bonding film and the second bonding film, and a though-substrate-via formed in the second semiconductor die from the bottom side thereof, wherein the though-substrate-via passes through the first bonding film and the second bonding film for electrically connecting to the first semiconductor die.

According to some embodiments of the present disclosure, a semiconductor package includes a stack of semiconductor dies and a through-substrate-via, the through-substrate-via is configured to deliver a power signal from a bottom side of the stack of semiconductor dies to a top side thereof directly, wherein the through-substrate-via is integrated into a power rail system of the stack of semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor package, comprising:
providing a first semiconductor die on a first carrier substrate, wherein the first semiconductor die has a first power rail feature on top side thereof;
providing a second semiconductor die on a second carrier substrate, wherein the second semiconductor die has a second power rail feature on bottom side thereof;
forming a first bonding film on bottom side of the first semiconductor die and forming a second bonding film on top side of the second semiconductor die, wherein the first semiconductor die and the second semiconductor die are bonded to each other through the first bonding film and the second bonding film;
forming a though-substrate-via in the second semiconductor die from the bottom side thereof, wherein the though-substrate-via passes through the first bonding film and the second bonding film for electrically connecting to the first semiconductor die; and
forming a redistribution layer structure and a plurality of bumps on a bottom side of a semiconductor package having a stack of the first and second semiconductor dies.

2. The method of claim 1, wherein the first semiconductor die has a first interconnect structure on the bottom side thereof, and the second semiconductor die has a second interconnect structure on the top side thereof.

3. The method of claim 2, wherein the first semiconductor die has a first device layer disposed between the first interconnect structure and the first power rail feature.

4. The method of claim 2, wherein the second semiconductor die has a second device layer disposed between the second interconnect structure and the second power rail feature.

5. The method of claim 1, wherein the method further comprises:
forming a first bonding pad in the first bonding film, and forming a second bonding pad in the second bonding film, wherein the first semiconductor die and the second semiconductor die are bonded to each other through the first bonding pad and the second bonding pad.

6. The method of claim 1, wherein the method further comprises:
forming a post power rail feature on the bottom side of the semiconductor package having the stack of the first and second semiconductor dies before forming the redistribution layer structure and the plurality of bumps,
wherein at least one of the post power rail feature is disposed on and electrically connected to the through-substrate-via.

7. A semiconductor package, comprising:
a first semiconductor die has a first power rail feature on top side thereof;
a second semiconductor die has a second power rail feature on bottom side thereof;
a first bonding film disposed on bottom side of the first semiconductor die;
a second bonding film disposed on top side of the second semiconductor die, wherein the first semiconductor die and the second semiconductor die are bonded to each other through the first bonding film and the second bonding film; and
a though-substrate-via formed in the second semiconductor die from the bottom side thereof, wherein the though-substrate-via passes through the first bonding film and the second bonding film for electrically connecting to the first semiconductor die.

8. The semiconductor package of claim 7, wherein the first semiconductor die has a first interconnect structure on the bottom side thereof, and the second semiconductor die has a second interconnect structure on the top side thereof.

9. The semiconductor package of claim 8, wherein the first semiconductor die has a first device layer disposed between the first interconnect structure and the first power rail feature.

10. The semiconductor package of claim 8, wherein the second semiconductor die has a second device layer disposed between the second interconnect structure and the second power rail feature.

11. The semiconductor package of claim 7, further comprising a first bonding pad formed in the first bonding film, and a second bonding pad formed in the second bonding film, wherein the first semiconductor die and the second semiconductor die are bonded to each other through the first bonding pad and the second bonding pad.

12. The semiconductor package of claim 7, further comprising a post power rail feature disposed on a bottom side of the semiconductor package having a stack of the first and second semiconductor dies, wherein at least one of the post power rail feature is disposed on and electrically connected to the through-substrate-via.

13. The semiconductor package of claim 12, further comprising a redistribution layer structure and a plurality of bumps disposed on the bottom side of the semiconductor package having the stack of the first and second semiconductor dies.

14. The semiconductor package of claim 7, further comprising a redistribution layer structure and a plurality of bumps disposed on a bottom side of the semiconductor package having a stack of the first and second semiconductor dies.

15. A semiconductor package, comprising:
a stack of semiconductor dies; and
a through-substrate-via configured to deliver a power signal from a bottom side of the stack of semiconductor dies to a top side thereof directly, wherein the through-substrate-via is integrated into a power rail system of the stack of semiconductor dies.

16. The semiconductor package of claim 15, wherein the stack of semiconductor dies comprises a first bonding film disposed on bottom side of a first semiconductor die and a second bonding film disposed on top side of a second semiconductor die, wherein the first semiconductor die and the second semiconductor die are bonded to each other through the first bonding film and the second bonding film.

17. The semiconductor package of claim 16, wherein the through-substrate-via passes through the first bonding film and the second bonding film.

18. The semiconductor package of claim 16, wherein the stack of semiconductor dies further comprises a first bonding pad formed in the first bonding film and a second bonding pad formed in the second bonding film, wherein the first semiconductor die and the second semiconductor die are bonded to each other through the first bonding pad and the second bonding pad.

19. The semiconductor package of claim 16, wherein the power rail system comprises a first power rail feature disposed on top side of the first semiconductor die and a second power rail feature disposed on bottom side of the second semiconductor die.

20. The semiconductor package of claim 19, wherein the power rail system further comprises a post power rail feature disposed on a bottom side of the stack of the semiconductor dies, wherein at least one of the post power rail feature is disposed on and electrically connected to the through-substrate-via.
